(19) United States
(12) Patent Application Publication
(10) Pub. No.: US 2022/0102597 A1
(43) Pub. Date: Mar. 31, 2022

(54) LIGHT EMITTING DEVICES HAVING PROFILED SIDE SURFACES

(71) Applicants: Tek Beng LOW, Melaka (MY); Eng Wah TAN, Melaka (MY)

(72) Inventors: Tek Beng LOW, Melaka (MY); Eng Wah TAN, Melaka (MY)

(21) Appl. No.: 17/034,075

(22) Filed: Sep. 28, 2020

(51) Int. Cl. H01L 33/56; H01L 33/60

(52) U.S. Cl. CPC H01L 33/56; H01L 25/0753; H01L 33/60

(57) ABSTRACT

A light emitting diode package, including a substrate having a side surface, wherein the substrate is adapted for mounting one or more light emitting diode light sources thereon; one or more light emitting diode light sources mounted to the substrate; a light conversion component that converts incident light emitted from the one or more light emitting diode light sources; a light reflective encapsulation component having an outermost side surface; and wherein the outermost side surface of the light reflective encapsulation component forms a step with the side surface of the substrate, and wherein both surfaces are non-coplanar.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A SEQUENCE LISTING

Not applicable.

### BACKGROUND OF THE INVENTION

### 1. Field of the Invention

The present invention relates in general to light emitting devices, and, more particularly, to improved light emitting diode (LED) packages that have profiled (e.g., bi-level or non-coplanar) side surfaces. The present invention further relates to methods for manufacturing LED packages with profiled side surfaces. The LED packages having profiled side surfaces of the present invention increase substrate utilization by at least 20%. Furthermore, the methods for manufacturing the LED packages with profiled side surfaces decrease blade wear out by at least 25% because, among other reasons, only a single type of hardness material is cut with each pass.

### 2. Background Art

By way of background, and as is shown in prior art FIG. 1, U.S. Pat. No. 9,853,194 appears to disclose a light emitting apparatus, comprising: (a) a mount substrate; (b) at least one light emitting device mounted on a planar surface of said mount substrate in a flip-chip manner; (c) a light transparent member that receives incident light emitted from the light emitting device; (d) a covering member, (e) wherein the light transparent member is a light conversion member that has an externally exposed light emission surface and a side surface contiguous to the light emission surface (f) wherein the covering member contains a light reflective material, and covers at least the side surface of the light transparent member, (g) wherein an outermost side surface of the covering member is coplanar (emphasis added) with an outermost side surface of the mount substrate, and (h) wherein the planar surface of the mount substrate on which the light emitting device is mounted extends to the outermost side surface of the mount substrate.

It will be understood that the light emitting apparatus structures and configurations disclosed in U.S. Pat. No. 9,853,194 are wasteful of substrate material. They also result in increased blade wear out during fabrication because the blade is engaging multiple materials each having substantially different physical properties (e.g., hardness, etcetera).

The present invention discloses improved light emitting diode packages that include profiled or non-coplanar side surfaces. Such configurations increase substrate utilization by at least 20%.

Furthermore, the methods for manufacturing the LED packages with profiled side surfaces decrease blade wear out by at least 25% because, among other reasons, only a single type of hardness material is cut with each pass.

By way of additional background, LED packages and encapsulants associated with LED packages have been known in the art for years, and are the subject of a plurality of patents and publications, including: U.S. Pat. No. 9,559,275 entitled “Light Emitting Device Package and Light Unit Having the Same,” U.S. Pat. No. 8,564,005 entitled “Light-Emitting Device Package,” U.S. Pat. No. 8,394,675 entitled “Manufacturing Light Emitting Diode (LED) Packages,” U.S. Pat. No. 8,314,479 entitled “Leadframe Package with Recessed Cavity for LED,” U.S. Pat. No. 7,646,029 entitled “LED Package Methods and Systems,” U.S. Pat. No. 6,407,411 entitled “LED Lead Frame Assembly,” United States Patent Application Publication Number 2005/0179041 entitled “Illumination System with LEDs,” United States Patent Application Publication Number 2005/0006794 entitled “Silicone Rubber Composition, Light-Emitting Semiconductor Embedding/Protecting Material and Light-Emitting Semiconductor Device,” United States Patent Application Publication Number 2003/0116769 entitled “Light Emission Diode Package,” United States Patent Application Publication Number 2002/0180345 entitled “Package Structure Containing Two LEDs,” International Application Publication Number WO 2015/059258 entitled “LED Encapsulant,” International Application Publication Number WO 2009/082177 entitled “Light Emitting Diode Package,” and International Application Publication Number WO 2009/072786 entitled “LED Package and Method for Fabricating the Same”—all of which are hereby incorporated herein by reference in their entirety including all references cited therein.

U.S. Pat. No. 9,559,275 appears to disclose a light emitting device package. The light emitting device is a package body that includes a first recess which is provided with a bottom face and a plurality of inner walls surrounding the bottom face, the plurality of inner walls including a first inner wall and a second inner wall, which are opposing walls; a lead frame exposed at the bottom face of the package body, the lead frame including a bottom frame and a reflector exposed along one of the first inner wall and the second inner wall; a light emitting element provided on the lead frame; and a transparent material provided in the package body to cover the light emitting element. A material of the reflector is the same as a material of the bottom frame of the lead frame.

U.S. Pat. No. 8,564,005 appears to disclose a light-emitting device package including: a package main body including a cavity and a lead frame including a mounting portion disposed in the cavity and a plurality of terminal portions; a light-emitting device chip mounted on the mounting portion; a plurality of bonding wires for electrically connecting the plurality of terminal portions and the light-emitting device chip; a light-transmitting encapsulation layer filled in the cavity; and a light-transmitting cap member disposed in the cavity and blocking the encapsulation layer to contact the plurality of bonding wires.

U.S. Pat. No. 8,394,675 appears to disclose a method of manufacturing an LED package that includes mounting a large panel frame/substrate (LPF/S) having a substantially square shape to a ring. The LPF/S includes a plurality of die pads and a corresponding plurality of leads arranged in a matrix pattern. Each of the die pads includes a planar chip attach surface. An LED chip is attached to the planar chip attach surface of each of the die pads. An encapsulant material is applied overlaying the LED chips and at least a part of the LPF/S. Each die pad and corresponding leads are separated from the LPF/S to form individual LED packages. The steps of attaching the LED chips and applying the encapsulant material are performed while the LPF/S is mounted to the ring.

U.S. Pat. No. 8,314,479 appears to disclose an LED package that includes a die pad having a bottom surface, an upper surface and a centrally located recessed cavity. The recessed cavity has a chip attach surface between the bottom surface and upper surface and sidewalls that extend from the recessed chip attach surface to the upper surface. The package additionally has leads arranged on opposing sides of the die pad. The leads have a bottom surface that is coextensive with the bottom surface of the die pad and an upper surface coextensive with the upper surface of the die pad. An LED chip is attached to the chip attach surface. The package further includes a package body having an encapsulant which fills space between the die pad and leads forming a bottom encapsulant surface that is coextensive with the bottom surfaces of the die pad and leads.

U.S. Pat. No. 7,646,029 appears to disclose methods and systems for LED modules that include an LED die integrated in an LED package with a sub-mount that includes an electronic component for controlling the light emitted by the LED die. The electronic component integrated in the sub-mount may include drive hardware, a network interface, memory, a processor, a switch-mode power supply, a power facility, or another type of electronic component.

U.S. Pat. No. 6,407,411 appears to disclose an improved LED lead frame packaging assembly that includes a thermally conducting, electrically insulating material that enhances the thermal conduction and structural integrity of the assembly, a UV-resistant encapsulant material, and an integral ESD material that reduces electrostatic discharge. The thermally conducting, electrically insulating material creates an electrically insulating, thermally conductive path in the lead frame assembly for dissipation of power and also acts as a mounting structure thus allowing for the use of a soft encapsulant material, preferably a silicone.

United States Patent Application Publication Number 2005/0179041 appears to disclose a system that includes a light emitting diode (LED), such as a projection system, which may be increased by using an LED chip that has a light emitting surface that emits light directly into any medium with a refractive index of less than or equal to approximately 1.25. For example, the LED chip may emit light directly into the ambient environment, such as air or gas, instead of into an encapsulant. The low refractive index decreases the étendue of the LED, which increases luminance. Moreover, without an encapsulant, a collimating optical element, such as a lens, can be positioned close to the light emitting surface of the LED chip, which advantageously permits the capture of light emitted at large angles. A secondary collimating optical element may be used to assist in focusing the light on a target, such as a micro-display.

United States Patent Application Publication Number 2005/0006794 appears to disclose a silicone rubber composition, comprising: (A) an organopolysiloxane containing at least two aliphatic unsaturated bonds; (B) an organopolysiloxane of resin structure comprising SiO₂ units, R³ₙR⁴ₚSiO_{0.5} units and R³_{q}R⁴ᵣSiO_{0.5} units wherein R³ is vinyl or allyl, R⁴ is a monovalent hydrocarbon group free of aliphatic unsaturation, n is 2 or 3, p is 0 or 1, n+p=3, q is 0 or 1, r is 2 or 3, and q+r=3; (C) an organohydrogenpolysiloxane having at least two SiH groups; and (D) a platinum catalyst cures into a silicone rubber having excellent rubbery and strength properties and little surface tack.

United States Patent Application Publication Number 2003/0116769 appears to disclose an LED package, made of ceramic substrates and having a reflective metal plate. This LED package consists of a first ceramic substrate, which has a chip mounting area on its top surface, and is provided with a predetermined conductive pattern formed around the chip mounting area. One or more LED chips are seated on the chip mounting area of the first ceramic substrate, and are connected to the conductive pattern. A second ceramic substrate is mounted on the top surface of the first ceramic substrate and has a cavity at a position corresponding to the chip mounting area. The reflective metal plate is set in the cavity of the second ceramic substrate to surround the LED chips. This LED package effectively controls the luminous intensity of the LED chips and the angular distribution of the luminance. The reflective metal plate also collaterally acts as a heat sink effectively dissipating heat from the LED chips to the surroundings of the LED package.

United States Patent Application Publication Number 2002/0180345 appears to disclose a package structure containing two LEDs (light emitting diodes), which are packaged in cascade and capable of emitting lights with different wavelengths. For example, by packaging a yellow LED die above a blue LED die or packaging a blue LED die above a yellow LED die, a desaturated blue, desaturated yellow or white light can be obtained when a blue light is emitted through a yellow light or a yellow light is emitted through a blue light. The present invention can be a single-anode-single-cathode or a double-anode-single-cathode package structure, wherein the latter structure can continually change the emitted light in a certain range by adjusting input voltages of the anodes.

International Application Publication Number WO 2015/059258 appears to disclose an LED encapsulant comprising a scattering particle mixture, which includes: (i) a linear polymer including a dimethylsiloxane group which has a vinyl end substituent and/or a linear polymer including a methylphenylsiloxane group which has a vinyl end substituent; and (ii) at least one vinyl-based resin selected from the group consisting of a vinyl-based ViMQ resin.

International Application Publication Number WO 2009/082177 appears to disclose a light emitting diode (LED) package that includes a light emitting diode (LED) package that includes a pair of lead frames connected with at least one LED chip through a metal wire, a package body integrally fixed with the lead frames and having a cavity having an open top, a lead frame bent downwardly to a lower part of an external mounting surface of the package body, a light-transmissive, transparent resin covering the LED chip and filling the cavity, a recess formed in a bottom surface of the cavity, in which the LED chip is mounted, and a transparent resin including a fluorescent material formed in the recess and the cavity. Accordingly, the amount of light-transmissive, transparent resin filling the cavity is reduced to save on manufacturing costs, and the height of the resin is lowered to improve the luminance of light. Also, the height of the package body is lowered, contributing to manufacturing a small product.

International Application Publication Number WO 2009/072786 appears to disclose an LED package that comprises a base having an LED chip mounted thereon, an encapsulation member formed by a light-transmittable resin to encapsulate the LED chip, and a housing formed to expose a top portion of the encapsulation member and to encompass a side surface of the encapsulation member, wherein the encapsulation member is formed by a transfer molding process using a mold to have a predetermined shape. Further, the housing may be light-transmittable.

While the above-identified patents and publications do appear to disclose a plurality of LED packages, none of the above-identified patents and publications appear to disclose an improved light emitting diode package that includes a bi-level and/or profiled side surface.

These and other objects of the present invention will become apparent in light of the present specification, claims, and drawings.

### SUMMARY OF THE INVENTION

The present invention is directed to a light emitting diode package comprising, consisting essentially of, and/or consisting of: (a) a substrate, wherein the substrate includes a side surface, and wherein the substrate is adapted for mounting one or more light emitting diode light sources or chips thereon; (b) one or more light emitting diode light sources associated with the substrate; (c) a light conversion component that converts incident light emitted from the one or more light emitting diode light source; (d) a light reflective encapsulation component that includes an outermost side surface; and (e) wherein the outermost side surface of the light reflective encapsulation component forms a step with the side surface of the substrate, and wherein both surfaces are not on the same plane.

The present invention is further directed to a light emitting diode package comprising, consisting essentially of, and/or consisting of: (a) a substrate; (b) a light emitting diode light source; (c) a light conversion component; (d) a light reflective encapsulation component; and (e) wherein a side surface of the light reflective encapsulation component and a side surface of the substrate are not on the same plane (e.g., profiled, bi-level, non-coplanar, etcetera).

The present invention is yet further directed to a method for manufacturing a light emitting diode package, comprising, consisting essentially of, and/or consisting of the steps of: (a) providing a light emitting diode package comprising: (1) a substrate, wherein the substrate includes a side surface, and wherein the substrate is adapted for mounting one or more light emitting diode light sources thereon; (2) at least one light emitting diode light source, wherein the at least one light emitting diode light source is associated with the substrate; (3) a light conversion component, wherein the light conversion component converts incident light emitted from the at least one light emitting diode light source; and (4) a light reflective encapsulation component, wherein the light reflective encapsulation component includes an outermost side surface; (b) cutting the outermost side surface of the light reflective encapsulation component with a first blade during a first pass; and (c) cutting the side surface of the substrate with a second blade during a second pass such that the outermost side surface of the light reflective encapsulation component forms a step with the side surface of the substrate, and wherein both surfaces are not on the same plane.

In a preferred embodiment of the present invention, the substrate comprises a ceramic and/or a transition metal.

In another preferred embodiment of the present invention, the substrate is fabricated from a material having a hardness of at least approximately (i.e., +/−15 percent) 8 GPa.

In yet another preferred embodiment of the present invention, the substrate is fabricated from a material ranging in hardness from approximately 8 GPa to approximately (i.e., +/−15 percent) 16 GPa.

In one embodiment of the present invention, the substrate comprises a hardness of at least approximately (i.e., +/−15 percent) 50 times that of the light reflective encapsulation component.

In a preferred embodiment of the present invention, the substrate comprises a hardness of at least approximately (i.e., +/−15 percent) 100 times that of the light reflective encapsulation component.

In another preferred embodiment of the present invention, the at least one light emitting diode light source is mounted on a planar surface of the substrate.

In yet another preferred embodiment of the present invention, the light reflective encapsulation component comprises an epoxy resin, a silicone resin, a modified-silicone resin, and combinations thereof.

In one embodiment of the present invention, the light reflective encapsulation component is fabricated from a material having a hardness of greater than approximately (i.e., +/−15 percent) Shore A10.

In a preferred embodiment of the present invention, the light reflective encapsulation component is fabricated from a material having a hardness of less than approximately (i.e., +/−15 percent) Shore D100.

In another preferred embodiment of the present invention, the light reflective encapsulation component is fabricated from a material ranging in hardness from approximately Shore A10 to approximately (i.e., +/−15 percent) Shore D100.

### BRIEF DESCRIPTION OF THE DRAWINGS

Certain embodiments of the present invention are illustrated by the accompanying figures. It will be understood that the figures are not necessarily to scale and that details not necessary for an understanding of the invention or that render other details difficult to perceive may be omitted.

It will be further understood that the invention is not necessarily limited to the particular embodiments illustrated herein.

The invention will now be described with reference to the drawings wherein:

FIG. 1 is a cross-sectional view of a prior art (FIG. 1 of U.S. Pat. No. 9,853,194) light emitting diode package augmented with a dashed line to show a co-planar relationship;

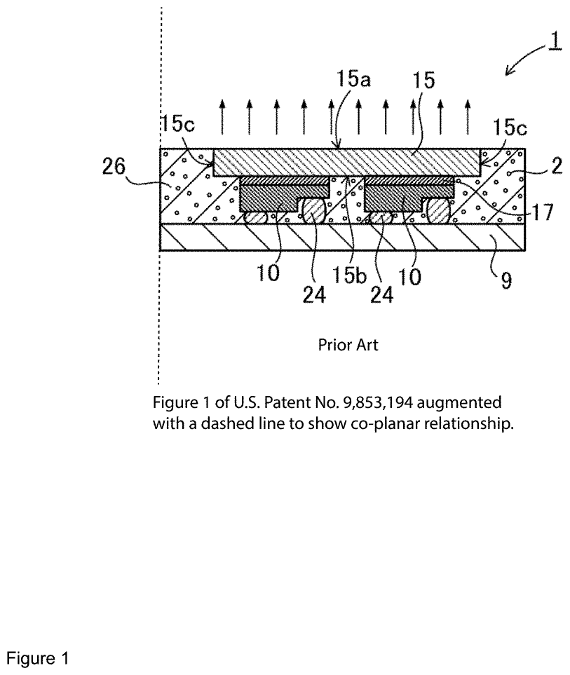

FIG. 2 is a cross-sectional view of a first embodiment of a profiled/bi-level light emitting diode package manufactured in accordance with the present invention;

FIG. 3 is a cross-sectional view of the method for manufacturing the profiled/bi-level light emitting diode package of FIG. 2;

FIG. 4 is a cross-sectional view of an alternative method for manufacturing a profiled/bi-level light emitting diode package; and

FIG. 5 is a cross-sectional view of an additional alternative method for manufacturing a profiled/bi-level light emitting diode package.

### DETAILED DESCRIPTION OF THE INVENTION

While this invention is susceptible of embodiment in many different forms, there is shown in the drawings and described herein in detail several specific embodiments with the understanding that the present disclosure is to be considered as an exemplification of the principles of the invention and is not intended to limit the invention to the embodiments illustrated.

It will be understood that like or analogous elements and/or components, referred to herein, may be identified throughout the drawings by like reference characters. In addition, it will be understood that the drawings are merely schematic representations of one or more embodiments of the invention, and some of the components may have been distorted from their actual scale for purposes of pictorial clarity.

As will be explained in greater detail hereinbelow, the present invention is directed to improved light emitting diode packages that have bi-level (e.g., non-coplanar) side surfaces.

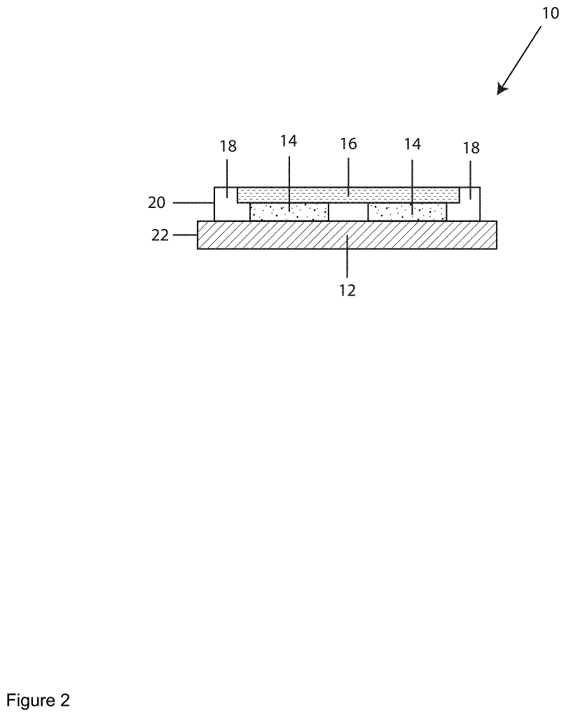

Referring now to FIG. 2, in a first embodiment of the present invention, light emitting diode package 10 generally includes: substrate 12, one or more light emitting diode light sources or chips 14; light conversion component 16; and light reflective encapsulation component 18. Outermost side surface 20 of light reflective encapsulation component 18 and side surface 22 of substrate 12 are not on the same plane (i.e., profiled, bi-level, non-coplanar, etcetera). It will be understood that one or both sides of light emitting diode package 10 are bi-level.

Substrate 12 is adapted for mounting one or more light emitting diode light sources or chips 14 thereon, and preferably comprises a ceramic and/or a transition metal. Substrate 12 is preferably fabricated from a material having a hardness of at least approximately (i.e., +/−15 percent) 8 GPa. In one embodiment of the present invention, substrate 12 is fabricated from a material ranging in hardness from approximately 8 GPa to approximately (i.e., +/−15 percent) 16 GPa. In this embodiment, substrate 12 preferably comprises a hardness of at least approximately (i.e., +/−15 percent) 50 times that of light reflective encapsulation component 18, and more preferably comprises a hardness of at least approximately (i.e., +/−15 percent) 100 times that of light reflective encapsulation component 18.

One or more light emitting diode light sources or chips 14 are preferably mounted on a planar surface of substrate 12.

Light conversion component 16 is positioned on top of at least a portion of the light emitting diode light sources or chips. During normal use it converts incident light emitted from the one or more light emitting diode light sources or chips. In certain embodiments, light conversion component 16 is integrated with or forms part of light reflective encapsulation component 18.

Light reflective encapsulation component 18 includes outermost side surface 20, and preferably comprises an epoxy resin, a silicone resin, a modified-silicone resin, and combinations thereof. In one embodiment of the present invention, light reflective encapsulation component 18 is fabricated from a material having a hardness of greater than approximately (i.e., +/−15 percent) Shore A10 and/or a hardness of less than approximately (i.e., +/−15 percent) Shore D100.

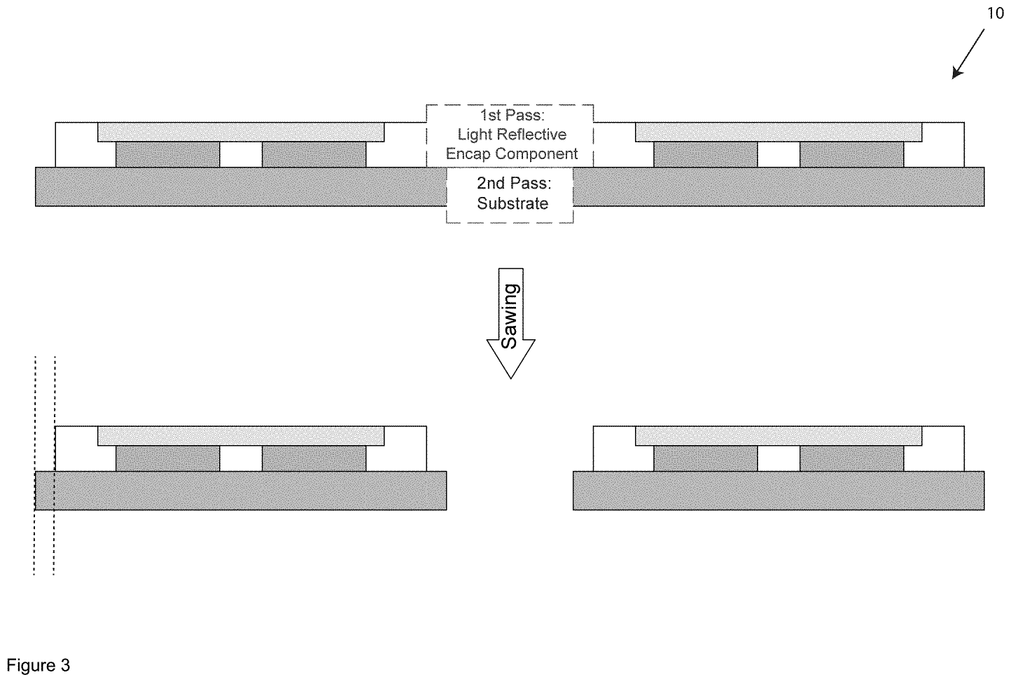

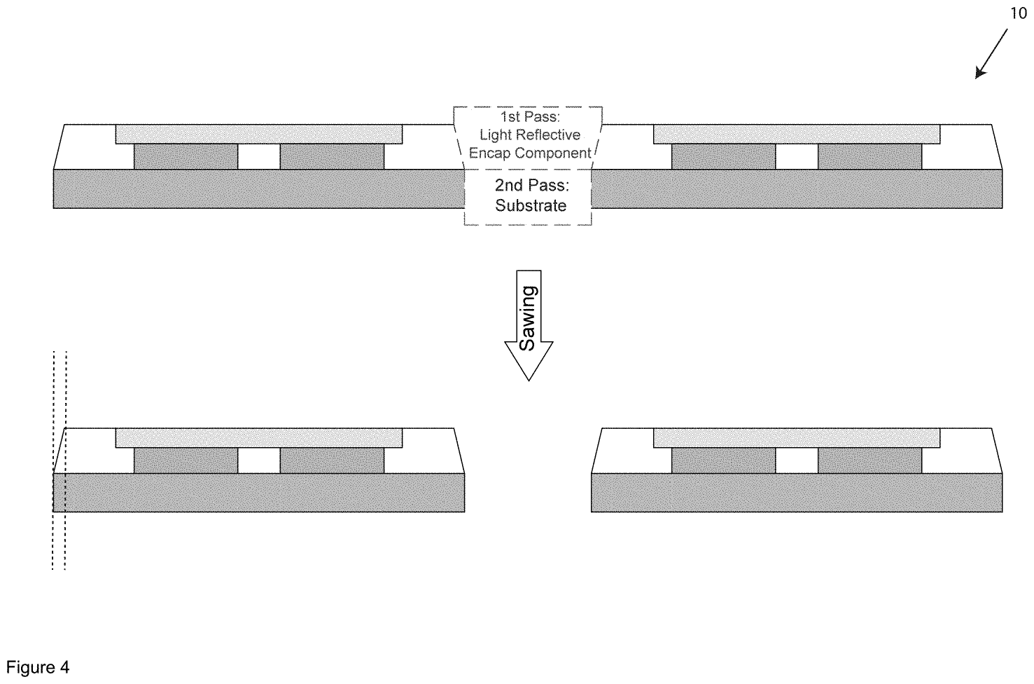

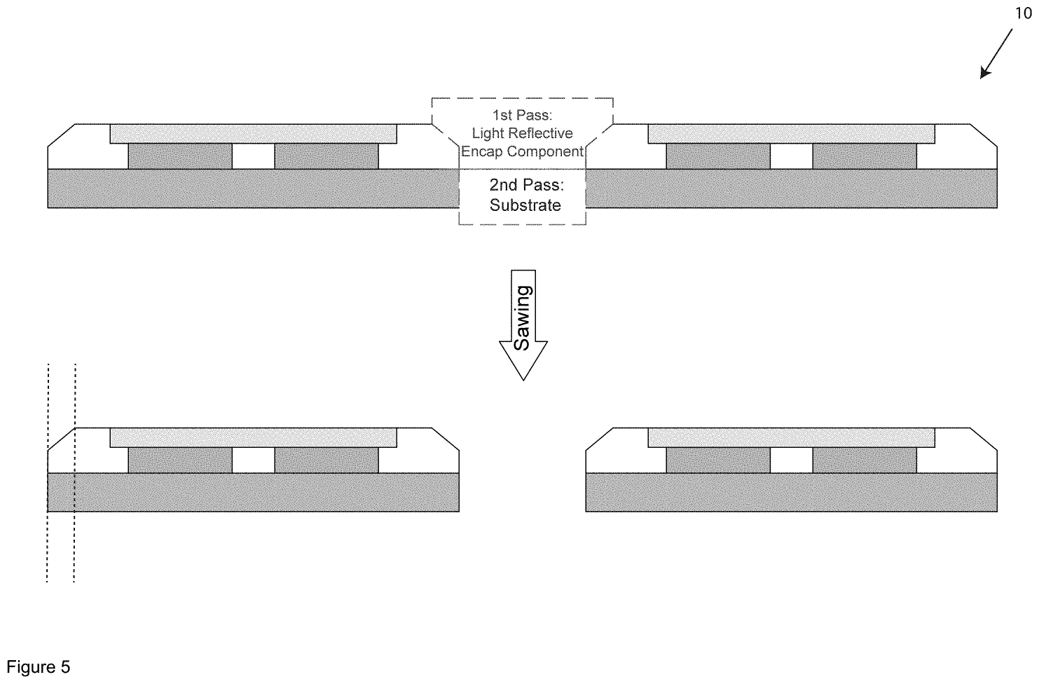

As is shown in FIGS. 3-5, the present invention is also directed to a method for manufacturing light emitting diode package 10. This method includes first providing a light emitting diode package comprising: (1) a substrate, wherein the substrate includes a side surface, and wherein the substrate is adapted for mounting one or more light emitting diode light sources thereon; (2) at least one light emitting diode light source, wherein the at least one light emitting diode light source is associated with the substrate; (3) a light conversion component, wherein the light conversion component converts incident light emitted from the at least one light emitting diode light source; and (4) a light reflective encapsulation component, wherein the light reflective encapsulation component includes an outermost side surface. Next, the outermost side surface of the light reflective encapsulation component is cut with a first blade during a first pass. The first pass is typically done using a wider, soft resin blade and only cuts up to the level of but not more than the light reflective encapsulation component. After the first pass, the side surface of the substrate is cut with a second blade during a second pass such that the outermost side surface of the light reflective encapsulation component forms a step with the side surface of the substrate. Hence these surfaces are not on the same plane. The second pass is typically done using a narrower saw blade than the first saw blade, and is fabricated from, for example, hard nickel, diamond, etcetera.

It will be understood that at least three different non-coplanar configurations are disclosed in FIGS. 3-5 using the methods of manufacturing of the present invention.

The foregoing description merely explains and illustrates the invention and the invention is not limited thereto except insofar as the appended claims are so limited, as those skilled in the art who have the disclosure before them will be able to make modifications without departing from the scope of the invention.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etcetera shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etcetera. As a non-limiting example, each range discussed herein can be readily broken down into a lower third, middle third and upper third, etcetera. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

What is claimed and desired to be secured by Letters Patent of the United States is:

1. A light emitting diode package, comprising:
a substrate, wherein the substrate includes a side surface, and wherein the substrate is adapted for mounting one or more light emitting diode light sources thereon;
at least one light emitting diode light source, wherein the at least one light emitting diode light source is associated with the substrate;
a light conversion component, wherein the light conversion component converts incident light emitted from the at least one light emitting diode light source;
a light reflective encapsulation component, wherein the light reflective encapsulation component includes an outermost side surface; and
wherein the outermost side surface of the light reflective encapsulation component forms a step with the side surface of the substrate, and wherein both surfaces are not on the same plane.

2. The light emitting diode package according to claim 1, wherein the substrate comprises a ceramic and/or a transition metal.

3. The light emitting diode package according to claim 1, wherein the substrate is fabricated from a material having a hardness of at least approximately 8 GPa.

4. The light emitting diode package according to claim 1, wherein the substrate is fabricated from a material ranging in hardness from approximately 8 GPa to approximately 16 GPa.

5. The light emitting diode package according to claim 1, wherein the substrate comprises a hardness of at least approximately 50 times that of the light reflective encapsulation component.

6. The light emitting diode package according to claim 1, wherein the substrate comprises a hardness of at least approximately 100 times that of the light reflective encapsulation component.

7. The light emitting diode package according to claim 1, wherein the at least one light emitting diode light source is mounted on a planar surface of the substrate.

8. The light emitting diode package according to claim 1, wherein the light reflective encapsulation component comprises an epoxy resin, a silicone resin, a modified-silicone resin, and combinations thereof.

9. The light emitting diode package according to claim 1, wherein the light reflective encapsulation component is fabricated from a material having a hardness of greater than approximately Shore A10.

10. The light emitting diode package according to claim 1, wherein the light reflective encapsulation component is fabricated from a material having a hardness of less than approximately Shore D100.

11. The light emitting diode package according to claim 1, wherein the light reflective encapsulation component is fabricated from a material ranging in hardness from approximately Shore A10 to approximately Shore D100.

12. A light emitting diode package, comprising:
a substrate;
a light emitting diode light source;
a light conversion component;
a light reflective encapsulation component; and
wherein a side surface of the light reflective encapsulation component and a side surface of the substrate are non-coplanar.

13. The light emitting diode package according to claim 12, wherein the substrate comprises a ceramic and/or a transition metal.

14. The light emitting diode package according to claim 12, wherein the substrate is fabricated from a material ranging in hardness from approximately 8 GPa to approximately 16 GPa.

15. The light emitting diode package according to claim 12, wherein the substrate comprises a hardness of at least approximately 100 times that of the light reflective encapsulation component.

16. The light emitting diode package according to claim 12, wherein the light reflective encapsulation component comprises an epoxy resin, a silicone resin, a modified-silicone resin, and combinations thereof.

17. The light emitting diode package according to claim 12, wherein the light reflective encapsulation component is fabricated from a material ranging in hardness from approximately Shore A10 to approximately Shore D100.

18. A method for manufacturing a light emitting diode package, comprising the steps of:
providing a light emitting diode package comprising:
a substrate, wherein the substrate includes a side surface, and wherein the substrate is adapted for mounting one or more light emitting diode light sources thereon;
at least one light emitting diode light source, wherein the at least one light emitting diode light source is associated with the substrate;
a light conversion component, wherein the light conversion component converts incident light emitted from the at least one light emitting diode light source; and
a light reflective encapsulation component, wherein the light reflective encapsulation component includes an outermost side surface;
cutting the outermost side surface of the light reflective encapsulation component with a first blade during a first pass; and
cutting the side surface of the substrate with a second blade during a second pass such that the outermost side surface of the light reflective encapsulation component forms a step with the side surface of the substrate, and wherein both surfaces are not on the same plane.

19. An LED manufactured according to the process of claim 18.
